(19) United States
(12) Patent Application Publication
(10) Pub. No.: US 2010/0024876 A1
(43) Pub. Date: Feb. 4, 2010

(54) Photon trapping solar cell

(76) Inventors: Richard L. McClary, Huntington Beach, CA (US); Charles Y. Tomita, Fullerton, CA (US)

Correspondence Address: Richard L. McClary;Solar Spectrum, LLC, Suite 205, 20201 S.W. Birch Street, Newport Beach, CA, 92660, US

(21) Appl. No.: 12/462,463

(22) Filed: Aug. 3, 2009

Related U.S. Application Data
(60) Provisional application No. 61/137,822, filed on Aug. 4, 2008.

(51) Int. Cl. H01L 31/00; H01L 31/18

(52) U.S. Cl. 136/256; 438/72; 257/E21.158

(57) ABSTRACT

A nano structure CdTe/CdS Photon Trapping Solar Cell (PTSC) comprising an ultra thin film stack construction of 2 layers, one each of Cadmium Sulfide and Cadmium Telluride, and wherein the bottom electrode is a reflecting sheet or plate that serves to reflect Photons unabsorbed by their pass through the material back through the layers of Cadmium Telluride and Cadmium Sulfide. The bottom metallic plate also serves as an electron conductor for allowing the photoelectric current to exit the device and perform useful work. The cell has a maximum efficiency of 40%.

### CROSS REFERENCE TO RELATED APPLICATIONS

This application claims the benefit of U.S. Provisional Application No. 61/137,822 filed Aug. 4, 2008, the contents of which are incorporated herein by reference.

### BACKGROUND OF THE INVENTION

Solar cell technology and design is rapidly converging to thin film CdTe techniques to reduce the high production cost of Silicon based solar cell technology. Thin film p-type CdTe with n-type CdS solar cells and systems have emerged as the one possible solution to replace Silicon solar cells. However, the conversion efficiency of thin film CdTe/CdS solar cells presently available are far short of Silicon Cells and have not reached a point where government subsidies are not required for effective commercialization to compete with conventional energy production. Typical proven efficiencies of only 9 percent are presently reported by large commercial companies. Today's CdTe/CdS solar cell systems designs cannot compete directly with the economic costs of oil and natural gas unless a major breakthrough in efficiency and cost is achieved by solar cell systems.

Researchers from across the country and the world are intensely searching for thin film solutions such as CdS/CdTe that exploits the low cost potentials of thin films and still produce the relatively high efficiencies of silicon solar cells. Researchers are on the right track as to the thickness issue by concentrating on thin film technologies. However, at optical wavelengths measured in angstroms, micron technologies appear to be extremely thick when dealing with energy conversion and propagation and reported efficiencies are extremely low as compared to Silicon cells. For examples, Jordan in U.S. Pat. No. 5,261,968 discusses an improved photovoltaic panel and method of forming a photovoltaic high efficiency CdTe/CdTe cell with a relatively thick design solution, wherein the relatively thick CdS layer is initially formed on a substrate, but its thickness is reduced during regrowth of the active photovoltaic layers. The effective thickness of the CdS layer would be much less but details on the physics of optimizing efficiencies based on exact thickness solutions of the phovoltaic junction of the p and n type material is not discussed (from the National Renewable Energy Laboratory, 0-7803-1220-1/93 IEEE). Zweibel et. al. reports a 13.4% efficient CdTe solar cell in “The U.S. DOE/NREL Polycrystalline Thin Film Photovoltaics Project”, Zweibel, K.; Ullal, H. S.; Mitchell, R. L.; Noufi, R., Photovoltaic Specialists Conference, 1991., Conference Record of the Twenty Second IEEE Volume, Issue , 7-11 Oct. 1991 Page(s): 1057-1061 vol. 2). In other reported efficiencies by Zweibel, Conventional Cadmium Telluride solar cells have efficiencies of less than 16.5% (K. Zweibel et. al., “Perspectives And Opportunities In Polycrystalline Thin-Film Photovoltaic Technologies” (Zweibel, K.; Ullal, H. S.; von Roedern, B. G.; Noufi, R.; Coutts, T. J.; Al-Jassim, M. M., Photovoltaic Specialists Conference, 1993., Conference Record of the Twenty Third IEEE Volume, Issue, 10-14 May 1993 Page(s): 379-388). General trends have been recognized as stated by Akhlesh Gupta, et.al. in his paper on “Effect of Thickness Reduction in High Efficiency CdS/CdTe Cells”, Materials Research Society, observing that increased efficiencies are possible as thickness of the photovoltaic junction is reduced.

As a result, there remains a great need to produce solar cells at low cost with high efficiency that require small amounts of critical raw materials.

### BRIEF SUMMARY OF THE INVENTION

The present invention provides a solution to the efficiency barrier of CdS/CdTe cells by radically changing the design process for obtaining solutions for material thicknesses in the photovoltaic region and in the capturing of energy resulting in much thinner CsS/CdTe cell designs.

The design approach for efficient solar energy designs was invented using first Principles of Quantum Mechanics coupled with Particle-Wave Duality. This unique process led to extremely thin CdTe/CdS Cell thicknesses whereby freed electrons traverse through the cell media with only a minimum chance of recombining with the CdTe molecules thus resulting in preservation of energy. In addition, the design is optimized for trapping reflected electrons to add the energy on multiple passes through the region thus further enhancing the energy conversion.

Although Cadmium is readily available, the implication of large CdS/CdTe solar cell systems when implemented worldwide would increase raw material demands unless only a small amount of raw Cadmium Sulfide and Cadmium Telluride material is used in the designs. Thin film solar cell designs are an answer but they would strain the demands of the raw CdS/CdTe material. A typical 3 micron thick CdTe solar cell would use an estimated 3 grams of CdTe per square meter, whereas the Nano Structure Photon Trapping Solar Cell (PTSC) would use 0.25 grams CdTE per square meter. The use of Nano Structure PTSC systems would put less impact to the world demands of Cadmium Telluride when PTSC is implemented in large power producing plants of miles in diameter, producing Giga Watts of prime power for the industrial grid. To the inventors' best knowledge, the efficiency of the PTSC System is estimated to be as much as four times higher than that of the known reported CdS/CdTe solar cell designs based on a recent patent search and available literature. Typical reported proven efficiencies of only 9 percent are presently reported by large commercial companies.

The implications of this Invention to the US and the world energy policies is extremely broad and PTSC would open a new era of energy production. The supply of energy from the sun is almost limitless and if PTSC can harness this energy at affordable costs, the world can generate almost limitless energy in electricity. The energies of the oceans can be harnessed. Ocean waters can be converted to hydrogen gases for supplying heat and fuel cell engines, water can be obtained for deserts and farming at low costs. Miles and miles of open desert areas can be turned into energy farms supplying giga watts of energy to the power grid.

The Nano Structure CdTe PTSC solar cell unique multi layer construction allows the formation of a photon trapping geometry which results in high energy conversions. A preferred embodiment of the present invention comprises a 2 stack design between 96.75 nm and 387 nm thick with the following parameters: the upper layer comprises n-type photoelectric material, preferably CdS, and the bottom layer comprises p-type photoelectric material, preferably CdTe. Further, electrodes are attached to the top and bottom of the 2 layer stack, wherein the bottom electrode is a metallic reflective conductive material, for example aluminum. The PTSC may further comprise an antireflective 1 over the top electrode that also functions to protect the structure underneath

### BRIEF DESCRIPTION OF THE VIEW OF THE DRAWING

FIG. 1 is a cross-sectional view of a preferred embodiment of the photon trapping Cadmium Telluride solar cell invention.

FIG. 2 is a diagram illustrating the operation of computer program, optical_stack.f.

FIG. 3 is a diagram illustrating the operation of computer program, optical_stack_opt.f.

### DETAILED DESCRIPTION OF THE INVENTION

The operation of this solar cell is similar to that of a standard optical antireflection coating used on windows and eyeglasses. An antireflection coating relies on the wave nature of light for its operation.

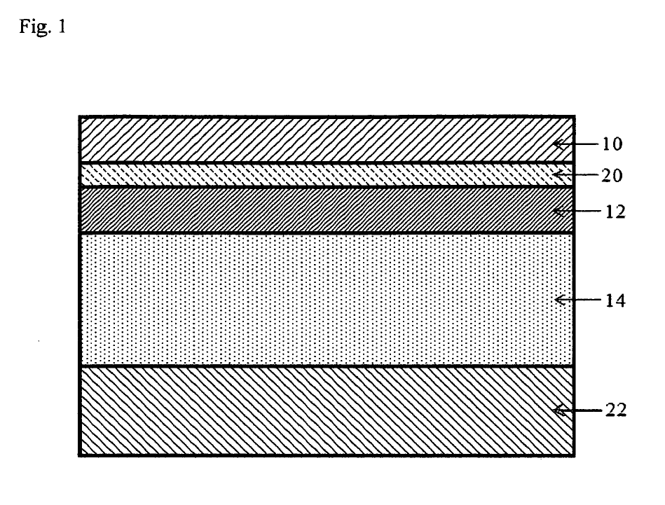

Referring to the invention represented by FIG. 1 in more detail, FIG. 1 as shown comprises a top transparent layer 10. Layer 10 comprises an antireflection layer that transmits the incident visible light energy to the layers underneath. Layer 20 is an electrode affixed to 10. Affixed underneath the conducting layer 20 is a layer comprising a n-type photoelectric material, shown as 12, preferably Cadmium Sulfide. Affixed underneath 12 is a layer comprising a p-type photoelectric material compatible with layer 12, preferably Cadmium Telluride, shown as 14. Affixed underneath 14 is a metallic reflective conducting electrode shown as 22. 22 should have a mirror like surface at the boundary with 14, in order to reflect photons that traverse the above layer without being absorbed, back through the photoelectric layers.

The top layer 10 serves as an antireflection layer designed to operate over the entire spectrum of visible light, comprising relative electric permittivity and thickness chosen to maximize the transmission of photons to layers 12 and 14. An antireflection layer has the material thickness designed so that light reflected at the boundary between two material layers with different indices of refraction has the opposite phase from the incoming light when it reaches the material boundary above and so is cancelled. This antireflection layer is necessary to transmit the light that strikes the top of 10 to the photoelectric layers 12 and 14. 10 can comprise transparent or near-transparent materials including but not limited to borosilicate glass, acrylic glass, transparent plastics, soda-lime glass, and ordinary transparent glasses. 10 further functions to protect the layers below and so is at least about 70 nm thick. However, with a thicker antireflective coating beyond 70 nm, there is a reduction in the PTSC's efficiency. For example, a coating of ⅛ inch thickness will reduce the overall efficiency by approximately 6% depending on the initial efficiency. In a preferred embodiment, 10 comprises a top layer of ordinary window glass from 70 nanometers thick to 1 inch thick.

Layer 20 comprises an electrically-conductive transparent layer also referred to as a top electrode, affixed between 10 and 12 that serves to allow electrons to return to the photovoltaic layers 12 and 14 below. A nonlimiting example of 20 is an open metallic grid that allows visible light through to the layers below. Preferably 20 comprises a transparent electrode with one or more sub-layers at least about 1000 nanometers in total thickness. More preferably such transparent electrode comprises at least one material including but not limited to Zinc Oxide and Indium Tin Oxide. Sub-layers of 20 may further comprise a high resistance transparent layer (HRT) to improve the cell efficiency, which is positioned as the bottom sub-layer of 20. In a preferred embodiment 20 comprises an upper sub-layer of Zinc Oxide doped with Aluminum with a thickness of at least 1000 nanometers, and a lower HRT sub-layer of undoped Zinc Oxide with a thickness of between 50 and 150 nanometers.

Layer 12 comprises an n-type photo-electric material, including but not limited to n-doped Silicon and Cadmium Sulfide. Preferably, 12 comprises Cadmium Sulfide. More preferably, 12 comprises Cadmium Sulfide with a thickness of between 26.75 nanometers and 107 nanometers. Layer 12 must be smoothly affixed to layer 14.

Layer 14 can comprise any p-type photoelectric material compatible with the dielectric constant of layer 12, including but not limited to Cadmium Telluride and p-doped Silicon. Preferably, layer 14 is Cadmium Telluride. More preferably, 14 is Cadmium Telluride with a thickness of between 70 and 280 nanometers. In a preferred embodiment, the combined thickness of layers 12 and 14 is between 96.75 and 387 nanometers. Since Cadmium Sulfide and Cadmium Telluride have the same relative dielectric constant, the thicknesses of layers 12 and 14 can individually vary as long as the combined thickness is from 96.75 and 387 nanometers. Variations from this combined thickness range will decrease the efficiency.

The overall efficiency of the photovoltaic structure is increased when the combined layers 12 and 14 are kept as thin as possible as long as the bottom CdTe layer is sufficiently effective in absorbing photons. This reduces the time for freed electrons to travel to the bottom conductor before being reabsorbed and losing the absorbed photon energy.

22 is an electrically-conductive reflective layer also referred to as a bottom electrode, affixed to layer 14, and gives the photovoltaic stack structural stability, serves as a conductor for the electrons freed by photons, and acts as a reflective surface that bounces photons that pass through the CdTe layer without being absorbed back through the CdTe layer. The CdS and CdTe layers create the photoelectric effect, a natural electric field that moves freed electrons to the bottom conductor. These electrons exit the bottom electrode through a wire, do work, and then are returned to the electrode on top of the CdS. The electrode must have a surface in contact with 14 that reflects light energy. The electrode comprises one layer or multiple sub-layers of any metal or combination of metals with a combined thickness of at least 100 nanometers, including but not limited to gold, copper, aluminum, and silver. In a preferred embodiment, the electrode comprises aluminum.

In further detail, photovoltaic cells of this invention can be used to convert light radiation into electrical power. Light comprised of photons is incident on the top antireflective coating 10, passing through to layer 14. Some of the incident photons strike atoms of the Cadmium Telluride layer of 14, freeing electrons. The freed electrons travel to the bottom electrode 22 where they flow to an attached wire to do work. The electrons then return to the top electrode 20, enter layer 12, then pass through to layer 14, completing the circuit. Photons that do not free an electron on the initial pass are reflected by the reflective electrode back through layer 14 where they may strike a molecule of Cadmium Telluride. Photons that do not strike a molecule on the second pass through layer 14 travel through to the top of layer 12. The thickness of 10, 12, and 14 are independently selected to exploit the wave nature of light, as expressed in the quantum mechanical principle of particle-wave duality, and captured light photons described above destructively or constructively interfere with the light incident on the top of 10, and bounce back through layers to the photoelectric layers 12 and 14. The CdS and CdTe material have similar optical indices of refraction, eliminating reflections from the interface of the two materials. The photons repeatedly bounce through layers 12 and 14, increasing their chances of sting a molecule and freeing an electron.

The thicknesses of 10, 12, and 14 are crucial to the operation of the device. The thicknesses depend upon the relative electric permittivity of layers 10, 12, and 14, and on the effective loss tangent, or imaginary part of the dielectric constant of the material of layer 14. These thicknesses are found by an optimization computer program that minimizes the light reflected from the top surface of 10. The optimization is performed for incident light wavelengths ranging from 400 nanometers to 796 nanometers. Photons with wavelengths longer than 796 nanometers are not energetic enough to free an electron from a Cadmium Telluride atom and are not absorbed because their energy is below that of the Cadmium Telluride band gap of approximately 1.56 electron volts. As non-limiting examples, for a relative Cadmium Telluride electric permittivity of 6.76 (relative index of refraction equal to 2.6), the top layer 10 is 70 nanometers thick, Layer 12 is 53.5 nanometers thick, layer 14 is 140 nanometers thick.

The relative thinness of layer 14 increases the probability that electrons freed by photons can travel to the electrode 22 without being reabsorbed. This increases the overall efficiency of the solar cell shown in the drawing compared to conventional solar cells. Conventional solar cells are usually much thicker than the device shown here. Freed electrons have a much greater distance to travel and this increases the time needed before reaching the bottom conductor. This in turn increases the chances for the freed electrons to be absorbed, thus losing their energy.

Here electric permittivity (for vacuum) is the quantity 8.8532×10⁻¹² farad/meter. Relative electric permittivity is the value of the electric permittivity relative to that of vacuum (relative permittivity=1.0). Antireflection coating refers to a 1 or multilayer transparent coating whose relative electric permittivities and thicknesses are chosen to minimize the reflection of any photons in the range of visible light (generally known in the art as 400 to 700 nanometers wavelength).

The thicknesses of these layers are found by two computer programs written in Fortran 77, optical_stack.f and optical_stack_opt.f (see block diagram below). Optical_stack.f analytically solves Maxwell's equations

\vec{∇}×\vec{E}=i ω μ \vec{H}−\vec{M}\vec{∇}·\vec{D}=σ

\vec{∇}×\vec{H}=−i ω ε \vec{E}+\vec{J}\vec{∇}·\vec{B}=σₘ(E^{-iωt} time dependence)

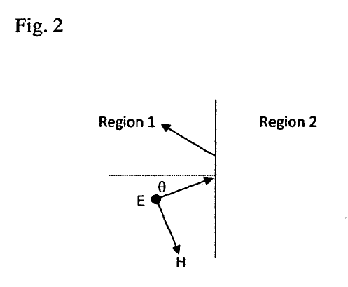

for an electromagnetic plane wave incident on the top layer of the stack at a given angle from normal incidence and at a given frequency. This is done by enforcing the correct boundary conditions at the boundaries of surfaces of the material stack. For example, for a material boundary at x=0, see FIG. 2:

E₁^{tan}=E₂^{tan}=ZJ (1)

H₁^{tan}=H₂^{tan}+E₂^{tan}/Z (2)

where
E₁^{tan}≡tangential component of incident+reflected E−field at x=0
E₂^{tan}≡tangential component of transmitted E−field at x=0
H₁^{tan}≡tangential component of incident+reflected H−field at x=0
H₂^{tan}≡tangential component of transmitted H−field at x=0
η₀≡\sqrt{μ₀/ε₀}≅377=free space impedance

The program used for this work is designed to make this computation at optical frequencies. The output of this computer program is the reflection coefficient of the reflected wave, expressed in decibals (dB). A decibal is 10.0 times the log to the base 10 of the reflected power relative to the power of the incident wave.

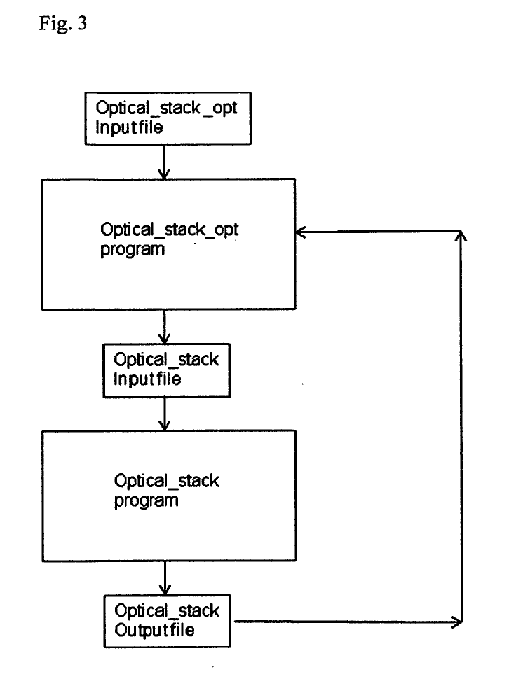

The second computer program as shown in FIG. 3 is an optimization program that implements the downhill simplex method (see, e. g. Numerical Recipes, by W. H. Press et. al. (Cambridge, Cambridge University Press, 1986), page 289). This program writes an input file to be used by the first program, calls the first program to compute the reflection coefficient, and then reads the output file of the optical_stack program. It computes a figure of merit for the set of parameter values, the repeats the process. Both of these Fortran programs are compiled by the open source GNU Fortran compiler. The quantities to be optimized are the thickness of each layer and the effective relative loss of the CdTe layer. The figure of merit of this computation is the largest reflection coefficient of the incident light waves at frequencies down to wavelengths of 796 nanometers. 796 nanometers corresponds to the longest wavelength of light that has enough energy to free an electron from a CdTe molecule, or 1.56 electron volts. Longer wavelengths of light do not have enough energy to be absorbed by the CdTe layer.

The three thicknesses of the three material layers as well as the effective relative electrical loss in the CdTe layer define a point on a four dimensional surface. The reflection coefficient of the incident light can be viewed as the height above this four dimensional surface. The downhill simplex, or amoeba method, starts with 5 initial sets of values. The incident values and the reflection coefficient, and 4 more sets of values consisting of the incident values with each of the four initial values increased by a percentage, for example, 20%. The optimizer then chooses a new set of values to move away from high points on the 4 dimensional surface.

Eventually, the optimizer can no longer reduce the largest reflection coefficient. The entire process then repeats with the initial parameter values consisting of the values that previously gave the lowest reflection coefficient. This happens in case the best set of values represent a local null on the four dimensional surfaces. Restarting the process sometimes allows the search to climb out of a local null and find a true global null. This is done because there is no optimization procedure yet discovered that can assure a global null.

This process optimizes a two layer antireflection coating along with the layers of CdS and CdTe. These programs are written to assume that all thicknesses are in thickness units of Angstroms. Since most optical thicknesses are currently expressed in nanometers (1 nanometer=10 Angstroms). The optical stack optimization code has been modified to compute the efficiency. It uses the measured solar spectrum. The maximum power in watts was computed for each 20 nanometer bin of the measured solar spectrum and power absorbed was computed for the incident light in each bin. The optimizer computes the power generated assuming that the photon absorption gives rise to an effective loss in the material stack. All photons at or above the 1.56 eV CdTe band gap are assumed to be absorbed and produce 1.56 eV of energy. Photon energy above 1.56 eV is assumed to be lost as heat. Photons with energy below 1.56 eV are not absorbed. The total solar energy incident on 1 square meter is 1000 watts using this solar power data set. A 165 nm thick CdTe/CdS layer was assumed. All freed electrons are assumed to travel to the bottom conductor without being re-absorbed. The optimization parameters are the thickness of the glass antireflection coating on top of the stack and the effective loss in the CdS/CdTe material.

The efficiency of the Nano Structure CdTe/CdS PTSC is limited by the band gap of the CdTe (approximately 1.56 electron volts). Photons entering the top of the cell that have energy below the band gap cannot free an electron. They escape through the top of the solar cell or are absorbed as heat. Photons with energy at or above the band gap energy can strike a molecule on one of its bounces through the CdTe and free an electron. The energy of any absorbed photon above that of the CdTe band gap is lost as heat. The thinness of the CdTe layer makes it likely that many photons will traverse the entire layer without being absorbed. Photons reaching the bottom conductor are reflected back through the CdTe. The thickness of the CdTe layer is optimized in this Invention so that photons reaching the top surface are 180 degrees out of phase with incident photons, preventing the photons from escaping and forcing them to make another pass through the CdTe layer, further increasing the chance of being absorbed. In this way the CdS and CdTe layers themselves act similar to an antireflection coating making this Invention unique.

The maximum efficiency of this type of solar cell is determined by the number of photons with energy above 1.56 electron volts that strike a CdTe atom and free an electron that travels to the bottom conductor. The PTSC solar cell design using the measured solar spectrum indicates that the maximum efficiency of this PTSC solar cell is 40%. This assumes that all photons with energy above the CdTe band gap are absorbed and that all freed electrons travel to the bottom conductor without being reabsorbed. When compared to the known existing standard CdTe solar cells of today, their efficiency is limited (Approximately 9%) because most electrons get reabsorbed by the thin film thickness (thousands of nanometers) CdTe before they can reach the bottom conductor. In this Invention, the Nano Structure PTSC solar cell, electrons need to travel only a maximum of 165 nanometers, greatly increasing the probability of them reaching the bottom conductor before being reabsorbed. Considering material impurities and crystalline imperfections in mass production of the PTSC, efficiencies of greater than 32 percent are achievable.

### EXAMPLE

Shown below is some of the output of a typical optimization run using programs optical_stack.f and optical_stack_opt.f. This run optimizes a two layer antireflection coating along with the layers of CdS and CdTe. These programs are written to assume that all thicknesses are in thickness units of Angstroms. Since most optical thicknesses are currently expressed in nanometers (1 nanometer=10 Angstroms), the final design thicknesses are converted from Angstroms to nanometers.

#AMOEBA SUMMARY FILE GENERATED Sat Mar 1 11:10:44 2008
#NUMBER OF ANGLES = 10
#Layer 1 Thick. Layer 2 Layer 3 Layer 4 loss Layer 4 Figure of merit
# 760.000 450.000 300.000 0.500 3000.000 −3.936
# 988.000 450.000 300.000 0.500 3000.000 −4.426
# 760.000 585.000 300.000 0.500 3000.000 −3.621
# 760.000 450.000 390.000 0.500 3000.000 −3.598
# 760.000 450.000 300.000 0.650 3000.000 −5.055
# 760.000 450.000 300.000 0.500 3900.000 −3.557
#END OF INITIALIZATION # 1
# 851.200 504.000 336.000 0.560 2100.000 −2.292
# 782.800 463.500 309.000 0.515 3450.000 −3.708
#... ~ 200 more iterations
#
#TOTAL TIME FOR JOB (SEC) = 62
#BEST PARAMETER VALUES AND FOM:
764.746 434.571 96.430 2.138 4570.444 −19.775

The optimizer computes the power generated assuming that the photon absorption gives rise to an effective loss in the material stack. All photons at or above the 1.56 eV CdTe band gap are assumed to be absorbed and produce 1.56 eV of energy. Photon energy above 1.56 eV is assumed to be lost as heat. Photons with energy below 1.56 eV are not absorbed. The total solar energy incident on 1 square meter is 1000 watts using this solar power data set. A 165 nm thick CdTe/CdS layer was assumed. All freed electrons are assumed to travel to the bottom conductor without being re-absorbed. The optimization parameters are the thickness of the glass antireflection coating on top of the stack and the effective loss in the CdS/CdTe material. The optimizer came up with 32.5% efficiency for the example shown below. The last few iterations of the optimizer are:

Efficiency Calculation

| | Anti reflection | CdS/CdTe | Efficiency |
|---|---|---|---|
| # | 769.219 | 3.644 | 0.675 |
| EFFICIENCY FOR ABOVE PARAMETERS = 32.474% | | | |
| # | 999.984 | 3.644 | 0.706 |
| EFFICIENCY FOR ABOVE PARAMETERS = 29.428% | | | |
| # | 769.219 | 4.737 | 0.679 |

EFFICIENCY FOR ABOVE PARAMETERS = 32.079%
# END OF P(MP,NP) INITIALIZATION # 3
#

What is claimed is:

1. A solar cell, comprising:
a transparent antireflection layer having a thickness of at least 70 nm;
an electrically-conductive transparent layer below the transparent antireflection layer having a thickness of at least 1000 nm;
a cadmium sulfide layer below the electrically-conductive transparent layer having a thickness of from 26.75 nm and 107 nm;
a cadmium telluride layer below the cadmium sulfide layer having a thickness of from 70 nm to 280 nm; and
an electrically-conductive reflective layer below the cadmium telluride layer having a thickness of at least 100 nm.

2. The solar cell of claim 1, wherein the transparent antireflection layer has a thickness of from 70 nm to 1 inch.

3. The solar cell of claim 1, wherein the transparent antireflection layer includes a glass layer.

4. The solar cell of claim 1, wherein the electrically-conductive transparent layer includes a transparent metal oxide layer.

5. The solar cell of claim 1, wherein the electrically-conductive transparent layer includes an electrically-conductive open metallic grid.

6. The solar cell of claim 1, wherein the cadmium sulfide layer has a thickness of about 53.5 nanometers.

7. The solar cell of claim 1, wherein the cadmium telluride layer has a thickness of about 140 nanometers.

8. The solar cell of claim 1, wherein cadmium sulfide layer and the cadmium telluride layer have a combined thickness of from 96.75 nm to 387 nm.

9. The solar cell of claim 8, wherein cadmium sulfide layer and the cadmium telluride layer have a combined thickness of about 193.5 nanometers.

10. The solar cell of claim 1, wherein the electrically-conductive reflective layer includes a metal layer.

11. The solar cell of claim 10, wherein the metal layer includes an aluminum layer.

12. A method of manufacturing a solar cell, comprising:
forming a transparent antireflection layer having a thickness of at least 70 nm;
forming an electrically-conductive transparent layer below the transparent antireflection layer having a thickness of at least 1000 nm;
forming a cadmium sulfide layer below the electrically-conductive transparent layer having a thickness of from 26.75 nm and 107 nm;
forming a cadmium telluride layer below the cadmium sulfide layer having a thickness of from 70 nm to 280 nm; and
forming an electrically-conductive reflective layer below the cadmium telluride layer having a thickness of at least 100 nm.

13. The method of claim 12, wherein the transparent antireflection layer is formed to a thickness of from 70 nm to 1 inch.

14. The method of claim 12, wherein forming the transparent antireflection layer includes forming a glass layer.

15. The method of claim 12, wherein forming the electrically-conductive transparent layer includes forming a transparent metal oxide layer.

16. The method of claim 12, wherein forming an electrically-conductive transparent portion includes forming an electrically-conductive open metallic grid.

17. The method of claim 12, wherein the cadmium sulfide layer is formed to a thickness of about 53.5 nanometers.

18. The method of claim 12, wherein the cadmium telluride layer is formed to a thickness of about 140 nanometers.

19. The method of claim 12, wherein the cadmium sulfide layer and the cadmium telluride layer are formed to a combined thickness of from 96.75 nm to 387 nm.

20. The method of claim 19, wherein the cadmium sulfide layer and the cadmium telluride layer are formed to a combined thickness of about 193.5 nanometers.

21. The method of claim 12, wherein forming the electrically-conductive reflective layer includes forming a metal layer.

22. The method of claim 21, wherein forming the metal layer includes forming an aluminum layer.

23. A method of converting light radiation into electrical power, comprising the steps of:
providing a solar cell, including: a transparent antireflection layer having a thickness of at least about 70 nm; an electrically-conductive transparent layer below the transparent antireflection layer, a cadmium sulfide layer below the electrically-conductive transparent layer having a thickness of from 26.75 nm to 107 nm; an cadmium telluride layer below the cadmium sulfide layer having a thickness of from 70 nm to 280 nm; and an electrically-conductive reflective layer below the cadmium telluride layer; and
drawing off power from the solar cell.

24. The method of claim 23, wherein the transparent antireflection layer has a thickness of from 70 nm and 1 inch.

25. The method of claim 23, wherein the transparent antireflection layer includes a glass layer.

26. The method of claim 23, wherein the electrically-conductive transparent layer includes a transparent metal oxide layer.

27. The method of claim 23, wherein the electrically-conductive transparent layer includes an electrically-conductive open metallic grid.

28. The method of claim 23, wherein the cadmium sulfide layer has a thickness of about 53.5 nanometers.

29. The method of claim 23, wherein the cadmium telluride layer has a thickness of about 140 nanometers.

30. The method of claim 23, wherein cadmium sulfide layer and the cadmium telluride layer have a combined thickness of from 96.75 nm to 387 nm.

31. The method of claim 30, wherein the cadmium sulfide layer and the cadmium telluride layer have a combined thickness of about 193.5 nanometers.

32. The method of claim 23, wherein the electrically-conductive reflective layer includes a metal layer.

33. The method of claim 32, wherein the metal layer includes an aluminum layer.
